(19) United States
(12) Patent Application Publication
(10) Pub. No.: US 2013/0248907 A1
(43) Pub. Date: Sep. 26, 2013

(54) SEMICONDUCTOR LIGHT-EMITTING DEVICE AND MANUFACTURING METHOD OF THE SAME

(71) Applicant: KABUSHIKI KAISHA TOSHIBA, Tokyo (JP)

(72) Inventors: Yuko KATO, Ishikawa (JP); Hidefumi YASUDA, Ishikawa (JP)

(73) Assignee: KABUSHIKI KAISHA TOSHIBA, Tokyo (JP)

(21) Appl. No.: 13/784,670

(22) Filed: Mar. 4, 2013

(30) Foreign Application Priority Data
Mar. 16, 2012 (JP) 2012-060933

(51) Int. Cl. H01L 33/62; H01L 33/60

(52) U.S. Cl. CPC H01L 33/62; H01L 33/60
USPC 257/98; 438/22

(57) ABSTRACT

A semiconductor light-emitting device is provided with a semiconductor layer including a first surface, a second surface opposite to the first surface, a luminous layer, and a first electrode formed on the first surface. The first surface has flat and rough portions. The first electrode has a pad and a fine wire electrode that is narrower than the pad. The fine wire electrode is formed on the flat portions but not on the rough portions. One or more metal contacts are disposed on the second surface to be under the rough portions.

### CROSS-REFERENCE TO RELATED APPLICATION

This application is based upon and claims the benefit of priority from Japanese Patent Application No. 2012-060933, filed Mar. 16, 2012, the entire contents of which are incorporated herein by reference.

### FIELD

Embodiments described herein relate to a semiconductor light-emitting device and a manufacturing method thereof.

### BACKGROUND

For a surface electrode formed on a surface (e.g., light-extracting surface) of a semiconductor layer including a luminous layer, a uniform current flow to the luminous layer is desirable. Unhindered light extraction from the surface of the semiconductor layer is also desirable. In addition, to increase light extraction efficiency, the light-extracting surface is typically a rough surface having recessed and projected regions. Unfortunately, an electrode coupled to the rough surface is likely to have an unduly high contact resistance.

### DESCRIPTION OF THE DRAWINGS

FIG. 1A is a schematic top view showing a semiconductor light-emitting device according to an embodiment.

FIG. 1B is a cross-section taken along line A-A′ in FIG. 1A.

FIG. 2A is a schematic top view showing a semiconductor light-emitting device according to an embodiment.

FIG. 2B is a cross-section taken along B-B′ in FIG. 2A.

FIG. 3 is a schematic cross-section showing a surface electrode of the embodiments.

FIGS. 4A-4D are schematic cross-sections of a semiconductor light-emitting device being manufactured according to an embodiment.

FIG. 5 is a schematic cross section view of a semiconductor light-emitting device according to an embodiment.

### DETAILED DESCRIPTION

Embodiments provide a semiconductor light-emitting device, which can improve a light-extraction effect, and a manufacturing method thereof.

In general, the embodiments will be explained with reference to the figures. Here, in each figure, the same symbols are given to the same elements.

According to this embodiment, the semiconductor light-emitting device is provided with a semiconductor layer, which includes a first surface, a second surface opposite to the first surface, a luminous layer, and a first electrode on the first surface. The first surface has flat and rough portions. The first electrode has a pad and a fine wire electrode that is narrower in width than the pad. The first electrode is formed on the flat portions but not on the rough portions. One or more metal contacts are disposed on the second surface to be under the rough portions.

### First Embodiment

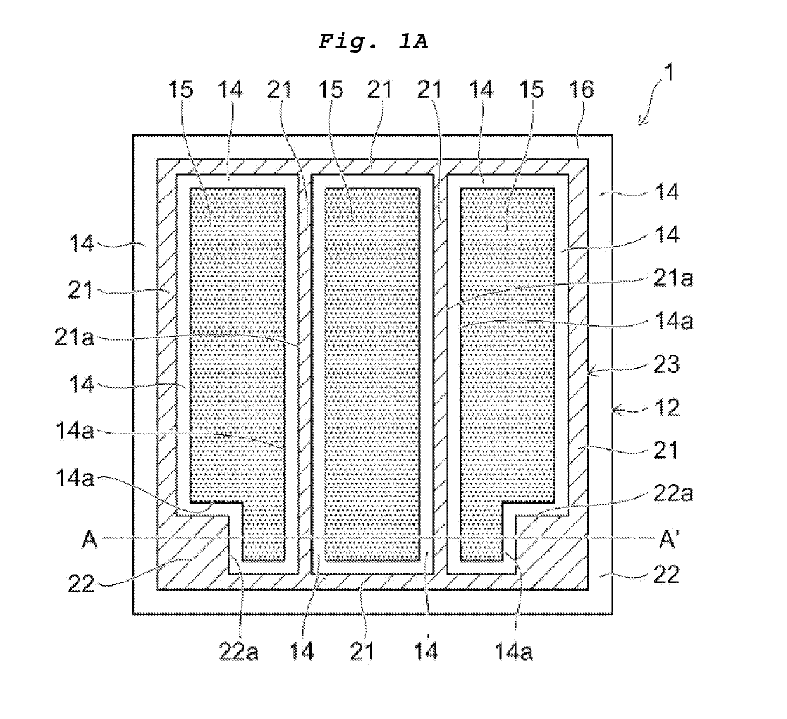

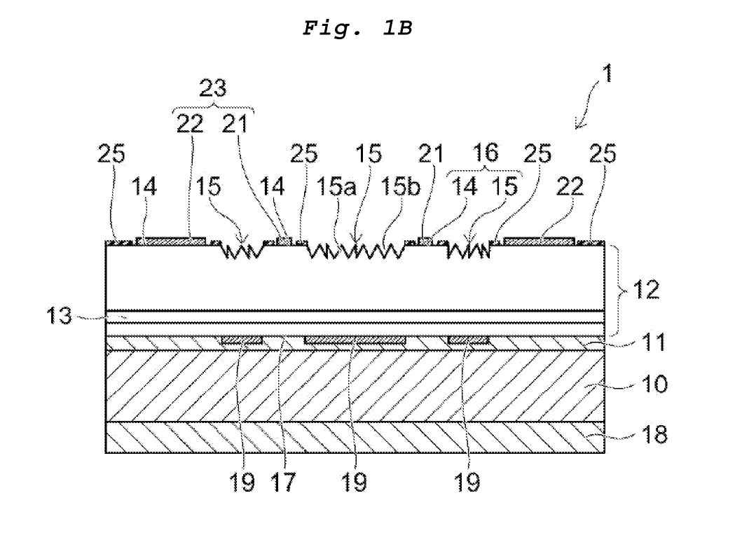

FIG. 1A is a schematic top view showing a semiconductor light-emitting device 1 of a first embodiment. FIG. 1B is a cross section along A-A′ of FIG. 1A.

In FIG. 1A, an insulating film 25 on a flat surface 14 shown in FIG. 1B is not shown. The insulating film 25, as will be described later, is a remaining section of a mask when a rough surface 15 is formed, and this insulating film sometimes does not remain on a flat surface 14.

The semiconductor light-emitting device 1 is provided with a substrate 10, a semiconductor layer 12 formed on the substrate 10, a surface electrode 23 as a first electrode formed on a first surface (e.g., light-extracting surface) 16 of the semiconductor layer 12, and a back electrode 18 as a second electrode formed on the back face of the substrate 10.

The semiconductor layer 12 includes the first surface 16, a second surface 17 at the opposite side of the first surface 16, and a luminous layer 13. The luminous layer 13 spreads over the entire surface of a chip. Through the surface electrode 23 and the back electrode 18, a current is supplied to the luminous layer 13, so that the luminous layer 13 emits lights.

The substrate 10 supports the semiconductor layer 12. The substrate 10 has electric conductivity between the semiconductor layer 12 and the back electrode 18. For example, a silicon substrate can be used. The back electrode 18, for example, is formed over the entire surface of the surface (e.g., back face) at the side opposite to the semiconductor layer 12 in the substrate 10. The back electrode 18 makes ohmic contact with the substrate 10.

For example, the semiconductor layer 12 is formed on a separate substrate (substrate for growth) suitable for epitaxial growth of the semiconductor layer 12 and joined with the substrate 10 via a metal layer 11. The metal layer 11 is positioned between the second surface 17 of the semiconductor layer 12 and the substrate 10.

The metal layer 11 has reflectivity to lights, which are emitted from the luminous layer 13, and also functions as a reflection layer for reflecting the lights emitted to the second surface 17 from the luminous layer 13 to the first surface 16.

On the second surface 17 of the semiconductor layer 12, metal contacts 19 are selectively formed. The metal contacts 19 make ohmic contact with the semiconductor layer 12.

The first surface 16 of the semiconductor layer 12 has a flat surface 14 and a rough surface 15. From a top view of the first surface 16, the total area of the rough surface 15 is wider than the total area of the flat surface 14.

The rough surface 15 has recessions and projections (e.g., several concave sections 15b and convex sections 15a) formed at random by etching, which will be described later. The convex sections 15a, for example, are formed in a pyramid shape. The size, shape, and pitch of the convex sections 15a are random.

The flat surface 14 is formed on the upper surface of a section formed in a mesa shape. The maximum height of the convex sections 15a is substantially the same as the height of the flat surface 14. Here, the height is based on the luminous layer 13 or second surface 17.

The surface electrode 23 has a pad 22 and a fine wire electrode 21 that is narrower (e.g., has a linear shape that is narrower) than the pad 22. The fine wire electrode 21 is formed on the flat surface 14 and is not formed on the rough surface 15. The pad 22 is also formed on the flat surface 14 and is not formed on the rough surface 15.

For example, the first surface 16 has a planar shape that is rectangular in shape, and the pads 22 are disposed in the vicinity of the two square sections of the first surface 16. An external terminal (e.g., bonding wire) for connection with an external circuit is joined with the pad 22.

The fine wire electrode 21 is connected with the pad 22. The pad 22 and the fine wire electrode 21, for example, are formed of substantially the same material by substantially the same process and also have substantially the same thickness.

The fine wire electrode 21 has a function of diffusing a current in the surface direction of the first surface 16 and is laid out without a bias in the surface direction of the first surface 16.

The rough surface 15, for example, is divided into three areas. From a top view of the first surface 16 shown in FIG. 1A, the left rough surface area is enclosed with the fine wire electrode 21 and the pad 22 disposed in the left lower square section, the middle rough surface area is enclosed with the fine wire electrode 21, and the right rough surface area is enclosed with the fine wire electrode 21 and the pad 22 disposed in the right lower square section. Any of three rough surface areas is enclosed with the flat surface 14 from a top view of the first surface 16 shown in FIG. 1A.

The lights emitted from the luminous layer 13 are mainly emitted to the outside of the semiconductor light-emitting device 1 from the rough surface 15 of the first surface 16. For the improvement of the light extraction efficiency from the rough surface 15, it is favorable for the working depth of the rough surface 15 or the height of the convex sections 15a to be near an emission wavelength or an emission wavelength or shorter of the luminous layer 13.

In this embodiment, the luminous layer 13, for example, emits light at a wavelength of 400 to 700 nm, and the maximum height of the convex sections 15a is 1 μm. In addition, the thickness of the surface electrode 23 is within twice the maximum height of the convex sections 15a, for example, 1 μm or smaller.

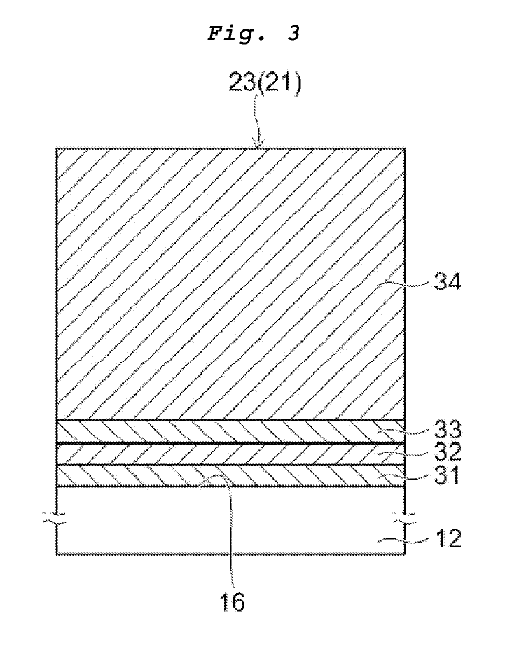

FIG. 3 shows the sectional structure of the surface electrode 23 according to an embodiment. The surface electrode 23 includes aluminum film 31, titanium film 32, platinum film 33, and gold film 34 sequentially laminated from the first surface 16 of the semiconductor layer 12. The thickness of the gold film 34 is greater than the thickness of the aluminum film 31, titanium film 32, and platinum film 33, and it is also thicker than the total film thickness of the aluminum film 31, titanium film 32, and platinum film 33. The aluminum film 31, titanium film 32, and platinum film 33 almost have substantially the same thickness, and the gold film 34 has a thickness that is about 14 times greater than the thickness of the aluminum film 31, titanium film 32, and platinum film 33.

The aluminum film 31 forms an alloy with the semiconductor layer 12 and functions as a metal contact in ohmic contact with the semiconductor layer 12. The titanium film 32 and the platinum film 33 function as barrier metals. Almost the entire thickness of the surface electrode 23 is occupied by the gold film 34 that has low resistance and excellent oxidation resistance and corrosion resistance.

As shown in FIG. 1B, the metal contact 19, which is formed on the second surface 17 of the semiconductor layer 12, is disposed under (back side) of the rough surface 15 and is not disposed under (back side) of the flat surface 14. The contact resistance of the semiconductor layer 12 and the metal contact 19 is lower than the contact resistance of the semiconductor layer 12 and the metal layer 11 for junction and reflection.

Here, as a comparative example, in case a surface electrode is formed on a recessed and projected rough surface, the thickness at some degree (e.g., about 5 μm) is required for the surface electrode to obtain good contact resistance with the semiconductor layer. However, a thick surface electrode increases the electrode material cost and the process time. In addition, a thick electrode on a light extracting surface hinders the extraction of light that is emitted in an oblique direction from the light-extracting surface.

On the contrary, according to this embodiment, the surface electrode 23 is formed on the flat surface 14 instead of on the recessed and projected rough surface 15. For this reason, the thickness of the surface electrode 23 required for obtaining good contact with the semiconductor layer 12 can be reduced, suppressing the electrode material cost and the process time.

According to this embodiment, while suppressing the thickness of the surface electrode 23 to 1 μm or smaller, good contact resistance with the semiconductor layer 12 can be obtained. As an example of the structure of the surface electrode 23, the laminated structure is mentioned with reference to FIG. 3. For example, the surface electrode 23 with the laminated structure shown in FIG. 3 has a thickness of 1 μm or smaller, and good contact with the flat surface 14 of the semiconductor layer 12, including the luminous layer 13, can be obtained.

In addition, if the surface electrode 23 is thinned, light, which is emitted in an oblique direction from the light-extracting surface and shielded by the surface electrode 23, can be reduced.

Moreover, the maximum height of the convex sections 15a on the rough surface 15 is substantially the same as the height of the flat surface 14. For this reason, the light emitted from the convex sections 15a can be suppressed from being shielded by a mesa-shaped section having the flat surface 14 on the upper surface.

According to this embodiment, the maximum height of the convex pars 15a (and the maximum depth of the concave sections 15b) is 1 μm or smaller, and the average height of the convex sections 15a (and the average depth of the concave sections 15b) is also 1 μm or smaller. In addition, the emission wavelength of the luminous layer 13 is about 400 to 700 nm. Therefore, the depth or height of the recession and projection workings is near the emission wavelength or the emission wavelength or shorter of the luminous layer 13, and a high light extraction efficiency can be obtained. These fine recessions and projections can be easily formed at low cost by random working through etching, which will be described later.

The metal contacts 19 formed on the second surface 17 of the semiconductor layer 12 are disposed under the rough surface 15 and are not disposed under the flat surface 14. For example, the metal contacts 19 are disposed at the back of a section in which the surface electrode 23 is not formed and are not disposed at the back of a section in which the surface electrode 23 is formed. However, the metal contacts 19 can sometimes have slightly overlapped under the flat surface 14 from a plan view.

The surface electrode 23 and the metal contact 19, which are respectively formed on the first surface 16 and the second surface 17 via the luminous layer 13, are not overlapped from a planar viewpoint. Therefore, the uniformity in the surface direction of a current, which is supplied to the luminous layer 13 through the surface electrode 23 and the metal contact 19, can be improved.

The surface electrode 23 (e.g., pad 22 and fine wire electrode 21) is not formed on the entire surface of the flat surface 14. An edge 22a at the rough surface 15 of the pad 22 and an edge 21a at the rough surface 15 of the fine wire electrode 21 are separated from the rough surface 15, as compared with an edge 14a of the flat surface 14 near the rough surface 15. The width of the fine wire electrode 21 (e.g., the width in the direction orthogonal to the longitudinal direction) is less than the width of the flat surface 14 (e.g., the width in the direction orthogonal to the longitudinal direction).

For example, the surface electrode 23 does not extend up to the edge 14a of the flat surface 14. On the flat surface 14, an area in which the surface electrode 23 is not formed (e.g., an area that is not attached with slant lines and dots in FIG. 1A) exists between the edge 14a of the flat surface 14 and the surface electrode 23. For this reason, along with the thin surface electrode 23, a further improvement of the light extraction efficiency in an oblique direction from the vicinity of the edge 14a in the flat surface 14 can be realized.

Here, the insulating film 25 on the flat surface 14 has transmittance for the light, which is emitted from the luminous layer 13, and is, for example, comprised of a silicon oxide film.

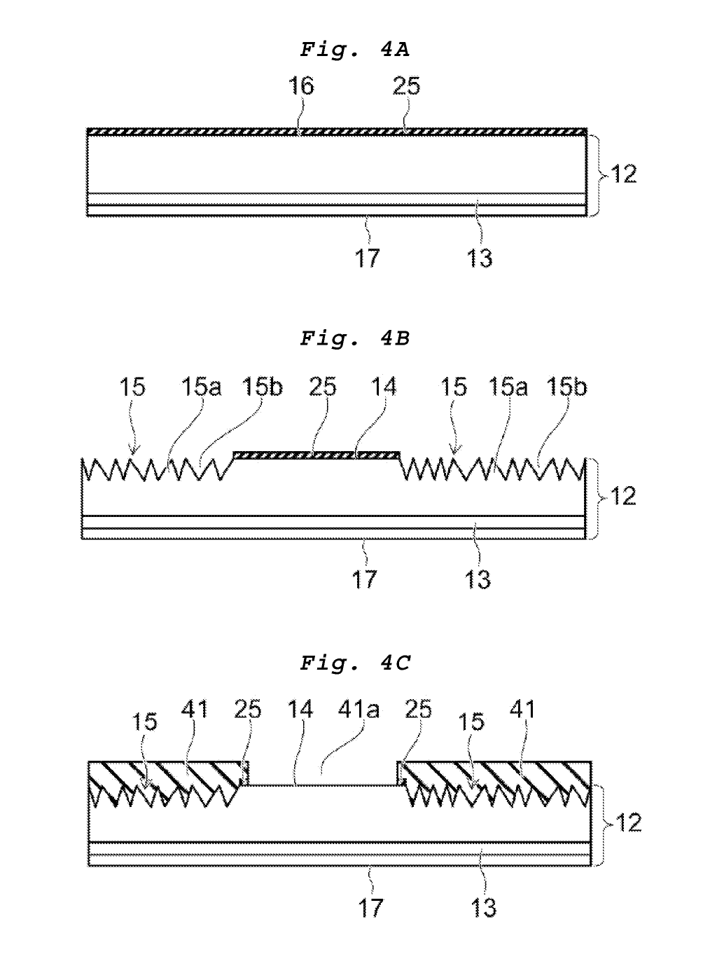

Next, the method for forming the rough surface 15 and the surface electrode 23 will be explained with reference to FIG. 4A to FIG. 4D. Here, in FIG. 4A to FIG. 4D, the structure below the semiconductor layer 12 is not shown.

First, as shown in FIG. 4A, the insulating film 25 is formed over the entire surface of the first surface 16 of the semiconductor layer 12. The insulating film 25 becomes a mask of etching for rough surface working, and for example, a silicon oxide film can be used.

The insulating film 25 formed on the entire surface of the first surface 16 undergoes patterning using a resist not shown in the figure. Therefore, the insulating film 25 remains selectively as an etching mask on the first surface 16.

Next, using the insulating film 25 as a mask, etching is carried out. Therefore, the rough surface 15 is formed as shown in FIG. 4B in an area that is not covered with the insulating film 25 of the first surface 16. Through anisotropic dry-etching (e.g., RIE (reactive ion etching)) as the etching method, recessions and projections are formed at random by the etching rate difference due to a difference of crystal planes. The surface that is covered with the insulating film 25 becomes the flat surface 14.

At that time, the maximum height of the convex sections 15a on the rough surface 15 is confined to being substantially the same height as that of the flat surface 14 by appropriately controlling the etching conditions (e.g., the etching time, the etching gas, etc.).

After forming the rough surface 15, a resist film 41 shown in FIG. 4C is formed on the rough surface 15 and the insulating film 25, and an opening 41a is formed in an area on the insulating film 25 in the resist film 41. The insulating film 25 is then etched using the resist film 41, in which the opening 41a has been formed, as a mask. Therefore, the flat surface 14 is exposed.

Next, the surface electrode 23 is formed on the resist film 41 and the exposed flat surface 14, for example, by a vapor deposition method, and the surface electrode 23 on the resist film 41 is lifted off (e.g., removed) along with the resist film 41. Therefore, as shown in FIG. 4D, the surface electrode 23 remains on the flat surface 14. The pad 22 and the fine wire electrode 21 are simultaneously, integrally formed of substantially the same material.

According to this embodiment, the recessions and projections of the rough surface 15 are formed at random by the etching rate difference due to the difference of the crystal planes. Therefore, without largely retreating the height of the convex sections 15a from the flat surface 14, the fine convex sections 15a (and concave sections 15b) with a height (and/or depth) near the emission wavelength or the emission wavelength or shorter of the luminous layer 13 can be easily formed.

It is unnecessary to form a mask on the convex sections 15a to leave the convex sections 15a with substantially the same height as that of the flat surface 14. Simply, only the section used as the flat surface 14 is covered with a mask, and the recessions and projections themselves of the rough surface 15 are formed without a mask. For example, a fine working of the mask corresponding to the fine recessions and projections is not required, which simplifies the process and does not increase manufacturing costs.

Here, after forming the rough surface 15, the insulating film 25 on the flat surface 14 may be removed, and then the resist film 41 may be formed. In this case, the insulating film 25 does not remain on the flat surface 14.

### Second Embodiment

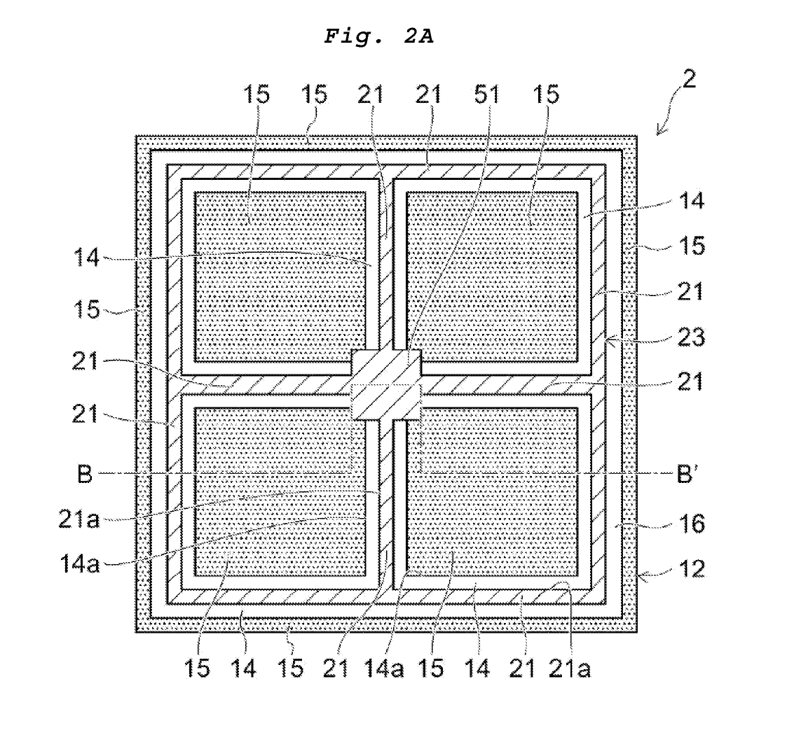

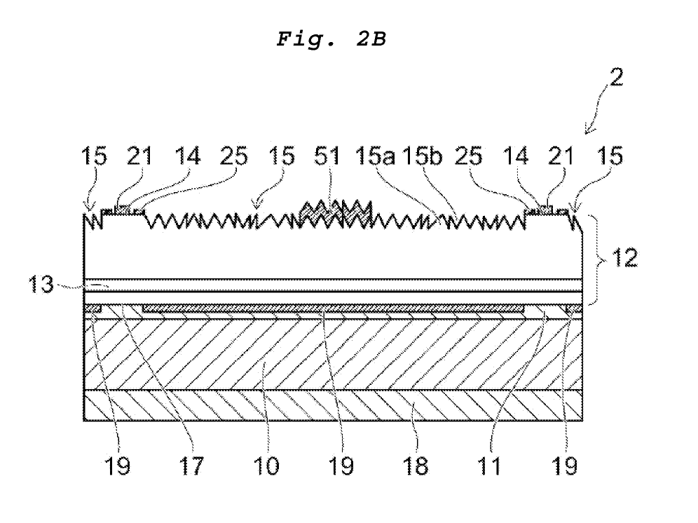

FIG. 2A is a schematic top view showing a semiconductor light-emitting device 2 of a second embodiment. FIG. 2B is a cross section along B-B′ of FIG. 2A. The same symbols are given to elements corresponding to the same elements as those of the first embodiment, and their detailed explanation may be omitted where it is duplicative of the explanations already provided in the first embodiment. In addition, in FIG. 2A, the insulating film 25 on the flat surface 14, as shown in FIG. 2B, is not shown.

In the second embodiment, the first surface 16 of the semiconductor layer 12 has the flat surface 14 and the rough surface 15. In addition, the surface electrode 23 has a pad 51 and the fine wire electrode 21 is narrower (e.g., has a linear shape that is narrower) than the pad 51. The fine wire electrode 21 is formed on the flat surface 14 and is not formed on the rough surface 15.

From a plan view of the first surface 16 shown in FIG. 2A, the pad 51 is disposed at the center of the first surface 16. An external terminal (e.g., bonding wire) for connecting to an external circuit is joined with the pad 51.

The pad 51 is formed on the rough surface 15, unlike in the first embodiment. The pad 51 is formed in a conformal shape along the recessions and projections of the rough surface 15, and recessions and projections on which the recessions and projections of the rough surface 15 have been reflected are formed on the upper surface of the pad 51. The average thickness of the pad 51 is, for example, 1 μm or smaller.

By thinning (e.g., regulated to 1 μm or smaller as an average thickness) the thickness of the pad 51 that is formed on the rough surface 15, the contact resistance of the pad 51 and the semiconductor layer 12 is higher than the contact resistance of the fine wire electrode 21, which is formed on the flat surface 14, and the semiconductor layer 12. Therefore, the current diffusion effect of the fine wire electrode 21 can be increased by suppressing the current concentration right under the pad 51.

The pad 51 and the fine wire electrode 21 are connected. The pad 51 and the fine wire electrode 21, for example, are integrally formed of substantially the same material by substantially the same process.

The maximum height of the convex sections 15a is 1 or less. In addition, the thickness of the fine wire electrode 21 is within twice of the maximum height of the convex sections 15a, for example, 1 μm or smaller.

In the second embodiment, as shown in FIG. 2B, the metal contact 19, which is formed on the second surface 17 of the semiconductor layer 12, is disposed under (back side) of the rough surface 15 and is not disposed under (back side) of the flat surface 14. For this reason, the uniformity in the surface direction of a current, which is supplied to the luminous layer 13 through the surface electrode 23 and the metal contact 19, can be improved.

According to the second embodiment, the fine wire electrode 21 is formed on the flat surface 14. For this reason, the thickness of the fine wire electrode 21 required for obtaining good contact with the semiconductor layer 12 can be thinned, reducing the electrode material cost and the process time. For example, while decreasing the thickness of the fine wire electrode 21 to 1 μm or smaller, good contact resistance with the semiconductor layer 12 can be obtained.

As an example of the structure of the fine wire electrode 21, the laminated structure is mentioned with reference to FIG. 3. For example, the laminated structure shown in FIG. 3 has a thickness of 1 μm or smaller, and good contact with the flat surface 14 of the semiconductor layer 12, including the luminous layer 13, can be obtained.

In addition, as previously mentioned, the average thickness of the pad 51, for example, is no thicker than 1 μm. Therefore, since the pad 51 and the fine wire electrode 21 that are formed on a light-extracting surface are thin, light, which is emitted in an oblique direction from the light-extracting surface and shielded by the pad 51 or fine wire electrode 21, can be reduced.

Moreover, in the second embodiment, the maximum height of the convex sections 15a on the rough surface 15 is also substantially the same as the height of the flat surface 14, and the average height of the convex sections 15a is not greater than the height of the flat surface 14. For this reason, the light emitted from the convex sections 15a can be suppressed from being shielded by a mesa-shaped section having the flat surface 14 on the upper surface.

In one embodiment, the maximum height of the convex sections 15a (and the maximum depth of the concave sections 15b) is 1 μm or less, and the average height of the convex sections 15a (and the average depth of the concave sections 15b) is also 1 μm or smaller. In addition, the emission wavelength of the luminous layer 13 is about 400 to 700 nm. Therefore, the depth or height of the recession and projection workings is near the emission wavelength or the emission wavelength or shorter of the luminous layer 13, and a high light extraction efficiency can be obtained. These fine recessions and projections, similar to the first embodiment, can be easily formed at low cost by random working through anisotropic dry-etching.

Moreover, the fine wire electrode 21 is not formed on the entire surface of the flat surface 14. The edge 21a at the rough surface 15 of the fine wire electrode 21 is separated from the rough surface 15, as compared with the edge 14a at the rough surface 15 of the flat surface 14. The width of the fine wire electrode 21 (e.g., the width in the direction orthogonal to the longitudinal direction) is smaller than the width of the flat surface 14 (e.g., the width in the direction orthogonal to the longitudinal direction).

For example, the fine wire electrode 21 does not extend up to the edge 14a of the flat surface 14. On the flat surface 14, an area in which the fine wire electrode 21 is not formed exists between the edge 14a of the flat surface 14 and the fine wire electrode 21. For this reason, along with the thin fine wire electrode 21, a further improvement of the light extraction efficiency in an oblique direction from the vicinity of the edge 14a in the flat surface 14 can be realized.

### Third Embodiment

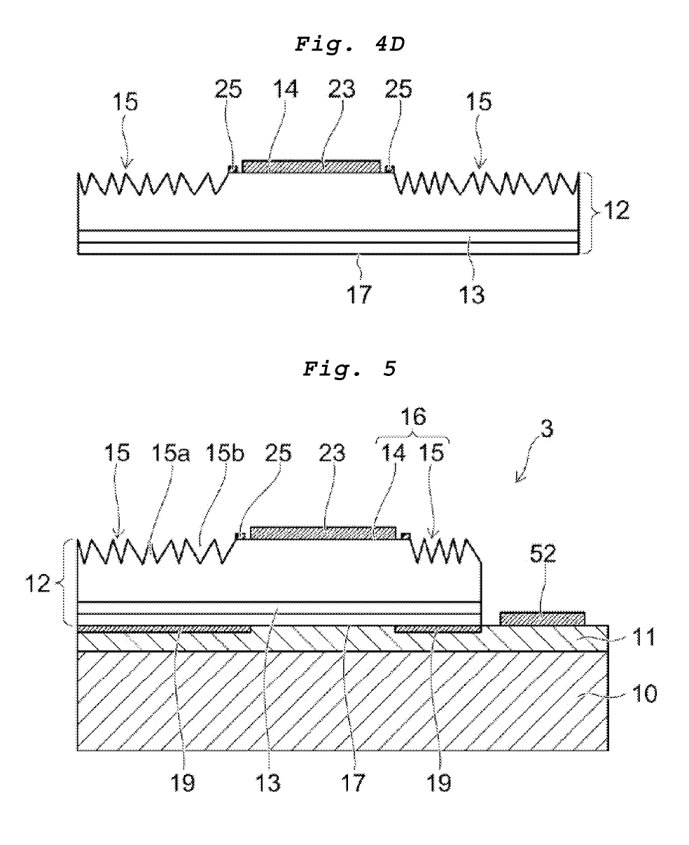

FIG. 5 is a schematic cross section showing a semiconductor light-emitting device 3 of a third embodiment.

In the first and second embodiments described above, the back electrode 18 is formed as the second electrode on the back face of the substrate 10. However, in the third embodiment shown in FIG. 5, a second electrode 52 is formed on the metal layer 11.

For example, there is an area on the metal layer 11 in which the semiconductor layer 12 is not formed, and the second electrode 52 is formed in that area. In this case, the substrate 10 may not be necessarily required to have electric conductivity.

While certain embodiments have been described, these embodiments have been presented by way of example only and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor light-emitting device, comprising:
semiconductor layers including a first surface having substantially flat and rough portions, a second surface opposite to the first surface, and a luminous layer between the first surface and the second surface; and
a first electrode formed on the first surface,
wherein the rough portions include concave sections and convex sections, and an uppermost position of the convex sections is at substantially the same position as the flat portions of the first surface in a direction perpendicular to the first surface.

2. The semiconductor light-emitting device according to claim 1, wherein the first electrode has a pad and a fine wire electrode that is narrower than the pad and is formed on the substantially flat portions of the first surface.

3. The semiconductor light-emitting device according to claim 1, further comprising one or more metal contacts disposed on the second surface under the rough portions.

4. The semiconductor light-emitting device according to claim 2, wherein a thickness of the fine wire electrode is less than twice of a maximum height of the convex sections.

5. The semiconductor light-emitting device according to claim 4, wherein a thickness of the fine wire electrode is 1 μm or less.

6. The semiconductor light-emitting device according to claim 2, wherein the pad and the fine wire electrode have substantially the same thickness.

7. The semiconductor light-emitting device according to claim 2, wherein the fine wire electrode includes an aluminum film, a titanium film, a platinum film, and a gold film sequentially laminated on the first surface.

8. The semiconductor light-emitting device according to claim 7, wherein a thickness of the gold film is greater than a thickness of the aluminum film, is greater than a thickness of the titanium film, and is greater than a thickness of the platinum film.

9. The semiconductor light-emitting device according to claim 7, wherein a thickness of the gold film is greater than a total film thickness of the aluminum film, the titanium film, and the platinum film.

10. The semiconductor light-emitting device according claim 2, wherein edges of the pad and the fine wire electrode are separated from the rough portions.

11. The semiconductor light-emitting device according to claim 1, wherein a maximum thickness of the convex sections is 1 μm or less.

12. The semiconductor light-emitting device according to claim 1, wherein the first electrode has a pad and a fine wire electrode that is narrower than the pad, the pad being formed on the first surface substantially flat portions, the fine wire electrode being formed on the substantially rough portions of the first surface.

13. The semiconductor light-emitting device according to claim 12, wherein an upper surface of the pad includes recessions and projections, and an average thickness of the pad is 1 μm or less.

14. The semiconductor light-emitting device according to claim 12, wherein a total area of the rough portions is greater than a total area of the substantially flat portions.

15. The semiconductor light-emitting device according to claim 12, further comprising:
a substrate with electric conductivity disposed on a side of the semiconductor layer having the second surface; and
a second electrode formed on a surface of the substrate that is on a side opposite to the semiconductor layer.

16. The semiconductor light-emitting device according to claim 12, further comprising:
a reflection layer that is formed on the second surface and that has reflectivity to light emitted from the luminous layer.

17. A method of manufacturing a semiconductor light-emitting device, comprising:
forming a mask on a first surface of a semiconductor layer having the first surface, a second surface opposite to the first surface, and a luminous layer;
forming rough portions on the first surface by etching several concave and convex sections in an area not covered with the mask; and
removing the mask to expose substantially flat portions and forming a first electrode at least partially on one or more of the substantially flat portions,
wherein an uppermost position of the convex sections is at substantially the same position as the flat portions of the first surface in a direction perpendicular to the first surface.

18. The method of claim 17, wherein the first electrode includes a pad and a fine wire electrode that is narrower than the pad, and the fine wire electrode is formed on the substantially flat portions but not on the rough portions.

19. The method of claim 18, wherein the pad is formed on the rough portions.

20. The method of claim 17, wherein the etching includes one of anisotropic dry-etching and reactive ion etching.
